(19) United States
(12) Patent Application Publication
(10) Pub. No.: US 2012/0049239 A1
(43) Pub. Date: Mar. 1, 2012

(54) GRAPHENE TRANSPARENT ELECTRODE, GRAPHENE LIGHT EMITTING DIODE, AND METHOD OF FABRICATING THE GRAPHENE LIGHT EMITTING DIODE

(76) Inventor: Chien-Min Sung, Danshuei Township (TW)

(21) Appl. No.: 12/938,822

(22) Filed: Nov. 3, 2010

(30) Foreign Application Priority Data
Sep. 1, 2010 (TW) 099129474

(51) Int. Cl. H01L 33/36; H01L 21/28; H01L 29/167

(52) U.S. Cl. 257/103; 257/613; 438/46; 257/E29.086; 257/E33.062; 257/E21.158; 977/734

(57) ABSTRACT

A graphene transparent electrode, which comprises: at least one graphene sheet; wherein the graphene sheets electrically connect with each other by overlapping with each other, each of the graphene sheets has a diameter from 10 μm to 1 mm, the quantity of the graphene sheets in the graphene transparent electrode is from 1 to 1000, the electrical resistance of the graphene transparent electrode is 1 Ω/cm or below, and the light transmittance of the graphene transparent electrode is 70% or above. A graphene light emitting diode (gLED) and a method of fabricating the same are also disclosed.

### BACKGROUND OF THE INVENTION

1. Field of the Invention

The present invention relates to a graphene transparent electrode, a graphene light emitting diode (gLED) comprising the same, and a method of fabricating the said gLED, more particularly, to a graphene transparent electrode comprising graphene sheets, a graphene light emitting diode (gLED) comprising the same, and a method of fabricating the said gLED.

2. Description of Related Art

In recent years, liquid crystal displays (LCD) have been applied as the displaying device for various electronics such as televisions or computer displays. For a liquid crystal display, a backlight source such as light-emitting diode (LED) or cold cathode fluorescent lamps (CCFL) should be used, because LCDs are not self-lighting devices. Also, optical films such as polarizer plates, light guide plates, or screen boards are used in a liquid crystal display. However, those optical films may result in the decreasing of the light transmittance of the LCDs, whereby the brightness of the LCDs cannot be efficiently increased. Besides, an LCD also has a disadvantage that an excellent black screen is hard to obtain, i.e. the light from the backlight source cannot be completely shielded with the liquid crystal displaying panel; hence light leakage may occur. Therefore the contrast and the coloring performance of the LCD cannot be improved. Moreover, long response time is also a technical problem hard to be solved in the LCD field.

In contrast, an organic light-emitting diode (OLED) is a good self-lighting displaying device, which does not need backlight sources. OLEDs have the advantages of being light-weight and slim (thickness less than 1 mm), with a wide view angle (about 170 degrees), low power consumption, fast response, high resolution, low heat discharge, flexible etc, whereby they have particularly drawn the attention of research and development specializing in screen technology.

Reference with FIG. 1, a conventional OLED is shown, which comprises: a substrate 11, a lower electrode 12, a light emitting layer 13, P-type semiconducting layer 14, an N-type semiconducting layer 15, and an upper electrode 16, in which the lower electrode 12 locates on the substrate 11, the light emitting layer 13 locates on the lower electrode 12, the P-type semiconducting layer 14 locates on the light emitting layer 13, the N-type semiconducting layer 15 locates on the P-type semiconducting layer 14, and the light emitting layer 13 is used to generate or control the combination of the electrons and the holes to luminesce. The lower electrode 12 (the anode) can be made of transparent material such as ITO. The P-type semiconducting layer can be made of carbon compounds comprising at least one trivalent nitrogen and aromatic tertiary amine comprising at least one aromatic ring.

However, the OLED projects still have some problem to be solved such as insufficient brightness (only 300 nit), short lifespan (less than 10,000 hours), and high manufacturing cost; furthermore, the thickness of the transparent electrode made of ITO not being able to be further reduced, which may result in an unfavorable light transmittance and electrical conductivity. Therefore, it is desirable to provide an improved novel OLED structure enable to increase the transparency and the conductivity thereof, to lower the manufacturing cost, and to mitigate those shortages of the conventional OLED.

### SUMMARY OF THE INVENTION

The present invention provides a graphene transparent electrode, which comprises: at least one graphene sheet; wherein the graphene sheets electrically connect with each other by overlapping with each other, each of the graphene sheets have a diameter from 10 μm to 1 mm, the quantity of the graphene sheets in the graphene transparent electrode is from 1 to 1000, the electrical resistance of the graphene transparent electrode is 1 Ω/cm or below, and the light transmittance of the graphene transparent electrode is 70% or above.

According to the present invention, the graphene sheets of the graphene transparent electrode have a two-dimensional structure with large area. The graphene transparent electrode of the present invention can serve as a transparent electrode and can be applied to various optical devices such as LCD, OLED, or solar cell, or other electronic devices. The graphene transparent electrode of the present invention comprises graphene sheets overlapping with each other, the transparency of the graphene transparent electrode of the present invention is high (70% or above), the resistance is 1 Ω/cm or below (more preferably 10⁻⁴ Ω/cm or below), and therefore is able to replace the conventional transparent ITO electrode. The graphene transparent electrode of the present invention is advantageous in being thin and having low power consumption, which cannot be achieved with a conventional ITO transparent electrode.

According to the graphene transparent electrode of the present invention, the graphene sheet is preferably doped with boron to form a P-type semiconducting layer; or the graphene sheet is preferably doped with nitrogen to form an N-type semiconducting layer.

According to the graphene transparent electrode of the present invention; the thickness of the graphene transparent electrode is preferably 10 nm to 1 mm, which is less than that of a conventional ITO transparent electrode. Besides, the graphene transparent electrode of the present invention has more advantages such as low resistance and high transparency.

According to the graphene transparent electrode of the present invention, the thickness of the graphene sheet is preferably 10 nm to 1 more preferably about 30 nm.

The present invention also provide a graphene light emitting diode (gLED), which comprises: a substrate; a graphene transparent electrode locating on the substrate and comprising plural of graphene sheets, wherein the graphene sheets electrically connect with each other by overlapping with each other; a light emitting layer locating on the graphene transparent electrode, a P-type semiconducting layer locating on the light emitting layer; an N-type semiconducting layer locating on the P-type semiconducting layer; and an upper electrode locating on the N-type semiconducting layer.

The graphene light emitting diode of the present invention is able to emit UV lights or blue lights; it can be applied to sterilization of food or photo-curing processing, for example. Comparing with a conventional ITO electrode, the graphene light emitting diode of the present invention comprising the graphene transparent electrode has a higher transparency, better electrical resistance, and thinner thickness. Besides, in the gLED of the present invention, if a graphene sheet doped with boron is used as the P-type semiconducting layer, and a graphene sheet doped with nitrogen or white graphite is used as the N-type semiconducting layer, the total thickness of the gLED of the present invention can be further reduced to meet the requirement of being minimized for electronics, and can be applied to more critical object such as rollable display, e-pictures, or e-papers.

The gLED of the present invention enables mobile communications to increase their transporting speed and image resolution. The gLED of the present invention also has the same advantages as those possessed by LEDs and OLEDs. When the substrate of the gLED of the present invention is a flexible plastic substrate such as PET plate, the gLED of the present invention can be applied as a flexible large area display or a rollable display.

The gLED of the present invention uses graphene as a raw material, and therefore the manufacturing cost can be largely lowered. Besides, due to a high transparency of the graphene sheets, the brightness of the gLED can be increased compared to conventional OLEDs. Also, a longer lifespan can be achieved according to the gLED of the present invention compared with a conventional OLED. The gLED of the present invention also has advantages such as being ultra thin, with high chromaticity, and low power consumption, and therefore the gLED of the present invention is of high commercial value.

According to the gLED of the present invention, the graphene sheets preferably has a diameter from 10 μm to 1 mm, the quantity of the graphene sheets in the graphene transparent electrode is preferably from 1 to 1000, the electrical resistance of the graphene transparent electrode is preferably 1 Ω/cm or below, more preferably 10⁻⁴ Ω/cm or below, and the light transmittance of the graphene transparent electrode is preferably 70% or above. Particularly, the graphene sheets of the graphene transparent electrode have a two-dimensional structure with large area.

According to the gLED of the present invention, the P-type semiconducting layer can be made of any materials applied in conventional OLEDs, and preferably can be made of graphene doped with boron. When graphene doped with boron is used as the material of the P-type semiconducting layer in the present invention, the thickness of the P-type semiconducting layer can be reduced and the semiconductivity can be improved compared with a conventional P-type semiconducting layer.

According to the gLED of the present invention, the N-type semiconducting layer can be made of any materials applied in conventional OLEDs, and preferably can be made of white graphite or graphene doped with nitrogen, more preferably graphene doped with nitrogen, in which the white graphite is hexagonal boron nitride. By using white graphite or graphene doped with nitrogen as the N-type semiconducting layer, the thickness of the N-type semiconducting layer can be reduced and the semiconductivity can be improved compared with a conventional N-type semiconducting layer. Moreover, by using graphene doped with nitrogen as the N-type semiconducting layer, the manufacturing cost of the N-type semiconducting layer can be largely reduced. More preferably the transparent electrode, the N-type semiconducting layer, and the P-type semiconducting layer are simultaneously made from graphene.

According to the gLED of the present invention, the light emitting layer can be made of any materials applied in conventional OLEDs, and preferably can be made of RGB fluorescent powder with host material or phosphorescent materials.

According to the gLED of the present invention, the substrate is preferably selected from a group consisted of: a glass substrate, a quartz substrate, a silicon substrate, and a plastic substrate.

According to the gLED of the present invention, the thickness of each graphene sheet preferably ranges from 10 nm to 1 μm, more preferably 30 nm. Therefore, the total thickness (about 10 nm to 1 mm) of the graphene transparent electrode can be thinner than a conventional ITO transparent electrode.

The gLED of the present invention preferably further comprises a reflective layer locating between the N-type semiconducting layer and the upper electrode, wherein the reflective layer can be made of silver.

The present invention further provides a method of fabricating a graphene light emitting diode (gLED), which comprises steps: (A) dipping a graphite film comprising plural of layered graphene sheets into an acid solution to separate the graphene sheets from each other, and obtain plural graphene sheets; (B) taking the graphene sheets out from the acid solution; (C) coating the graphene sheets on a substrate to form a graphene transparent electrode; (D) forming a light emitting layer on the graphene transparent electrode; (E) forming a P-type semiconducting layer on the light emitting layer; (F) forming an N-type semiconducting layer on the P-type semiconducting layer; and (G) forming an upper electrode on the N-type semiconducting layer.

The gLED made by the method of the present invention is able to emit UV lights or blue lights; therefore, it can be applied to a sterilization of food or photo-curing processing, for example. Comparing with a conventional ITO electrode, the gLED made by the method of the present invention comprising the graphene transparent electrode has a higher transparency, better electrical resistance, and lower thickness. Besides, in the gLED made by the method of the present invention, if a graphene sheet doped with boron is used as the P-type semiconducting layer, and a graphene sheet doped with nitrogen or white graphite is used as the N-type semiconducting layer, the total thickness of the gLED of the present invention can be further reduced to meet the requirement of being minimized for electronics, and can be applied to more critical object such as rollable display, e-pictures, or e-papers.

The gLED made by the method of the present invention enables the transporting speed and image resolutions of mobile communications to be increased. The gLED made by the method of the present invention further has the same advantages as those possessed by LEDs and OLEDs. When the substrate of the gLED made by the method of the present invention is a flexible plastic substrate such as PET plate, the gLED made by the method of the present invention can be applied as a flexible large area display or a rollable display.

The gLED made by the method of the present invention uses graphene as a raw material, and therefore the manufacturing cost can be largely lowered. Besides, due to a high transparency of the graphene sheets, the brightness of the gLED can be increased. Also, a longer lifespan can be achieved according to the gLED made by the method of the present invention compared with a conventional OLED. The gLED made by the method of the present invention also has advantages such as being ultra thin, with high chromaticity, and low power consumption, and therefore the gLED made by the method of the present invention is of high commercial value.

According to the method of fabricating a graphene transparent electrode of the present invention, the graphite film can be preferably fabricated by steps: (A1) providing a substrate; (A2) coating a graphite powder on the substrate to form a graphite layer on the substrate; and (A3) heat-treat the graphite layer formed on the substrate under vacuum or an oxygen-free atmosphere (by providing nitrogen or other inert gases).

According to the method of fabricating a graphene transparent electrode of the present invention, the temperature of the heat-treating of the step (A3) is preferably 1000° C. to 1500° C., more preferably about 1200° C.

According to the method of fabricating a graphene transparent electrode of the present invention, in the step (C), the graphene sheets are coated on the substrate preferably by a spin coating method.

According to the method of fabricating a graphene transparent electrode of the present invention, in the step (D), the light emitting layer is preferably made of RGB fluorescent powder with host material or phosphorescent materials, and the light emitting layer can be made by a printing method.

According to the method of fabricating a graphene transparent electrode of the present invention, in the step (C), the thickness of the graphene sheet is preferably 10 nm to 1 μm.

According to the method of fabricating a graphene transparent electrode of the present invention, in the step (C), when the graphene sheets are coated on the substrate, a magnetic field is preferably applied to assist alignment of the graphene sheets. Therefore, the transporting speed of the electrical current can be increased in a specific direction.

According to the method of fabricating a graphene transparent electrode of the present invention, in the step (B), a mesh such as a copper mesh with pore size of 1 μm to 100 μm is preferably used to remove the graphene sheets from the acid solution.

The method of fabricating a graphene transparent electrode of the present invention, after the step (B), may preferably further comprise a step (B1): washing the graphene sheets, taken out from the acid solution, with water.

According to the method of fabricating a graphene transparent electrode of the present invention, in the step (A), the acid is preferably selected from a group consisted of: sulfuric acid, hydrochloric acid, nitric acid, and a combination thereof.

According to the method of fabricating a graphene transparent electrode of the present invention, in the step (E), the P-type semiconducting layer is preferably made of graphene doped with boron, and the P-type semiconducting layer is preferably made by a spin coating method to coat the graphene sheets doped with boron on the graphene transparent electrode.

According to the method of fabricating a graphene transparent electrode of the present invention, in the step (F), the N-type semiconducting layer is a preferably white graphite layer or graphene layer doped with nitrogen, more preferably graphene layer doped with nitrogen, in which the white graphite is hexagonal boron nitride.

According to the method of fabricating a graphene transparent electrode of the present invention, the substrate is preferably selected from a group consisted of a glass substrate, a quartz substrate, a silicon substrate, and a plastic substrate.

Other objects, advantages, and novel features of the invention will become more apparent from the following detailed description when taken in conjunction with the accompanying drawings.

### BRIEF DESCRIPTION OF THE DRAWINGS

FIG. 1 is a schematic view of a conventional OLED;

FIG. 2 is a process flow chart of fabricating a gLED of the example 1;

FIG. 3 is a schematic view of a graphene transparent electrode of the example 1;

FIG. 4 a schematic view of a gLED provided by the example 1; and

FIG. 5 is a light transmittance versus electrical resistance testing result of the testing example.

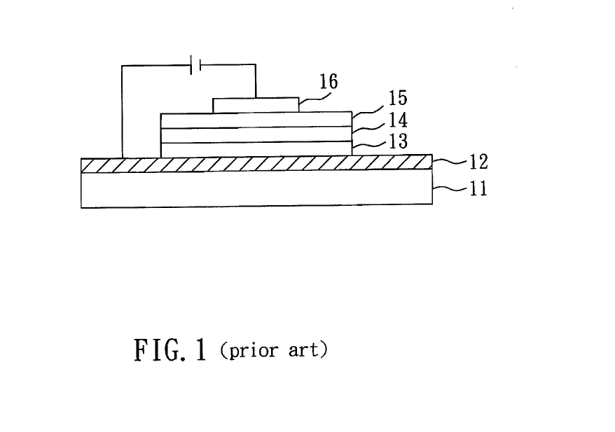

### DETAILED DESCRIPTION OF THE PREFERRED EMBODIMENT

Because of the specific embodiments illustrating the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

### Example 1

### The Providing of Graphite Film Comprising Plural Layered Graphene Sheets

The graphite film of the present example is made by a solid state method as described below.

First, a pure graphite powder is coated on a quartz substrate and then the quartz substrate coated with the graphite powder is placed in a tube-shape in a vacuum degree of 10⁻⁵ Torr.

Then, the quartz substrate coated with the graphite powder is heat treated at a temperature of 1200° C. to form a graphite film. After cooling, the formed graphite film is taken off from the quartz substrate to obtain the graphite film comprising plural of layered graphene sheets of the present example.

The Providing of Graphene Light Emitting Diode

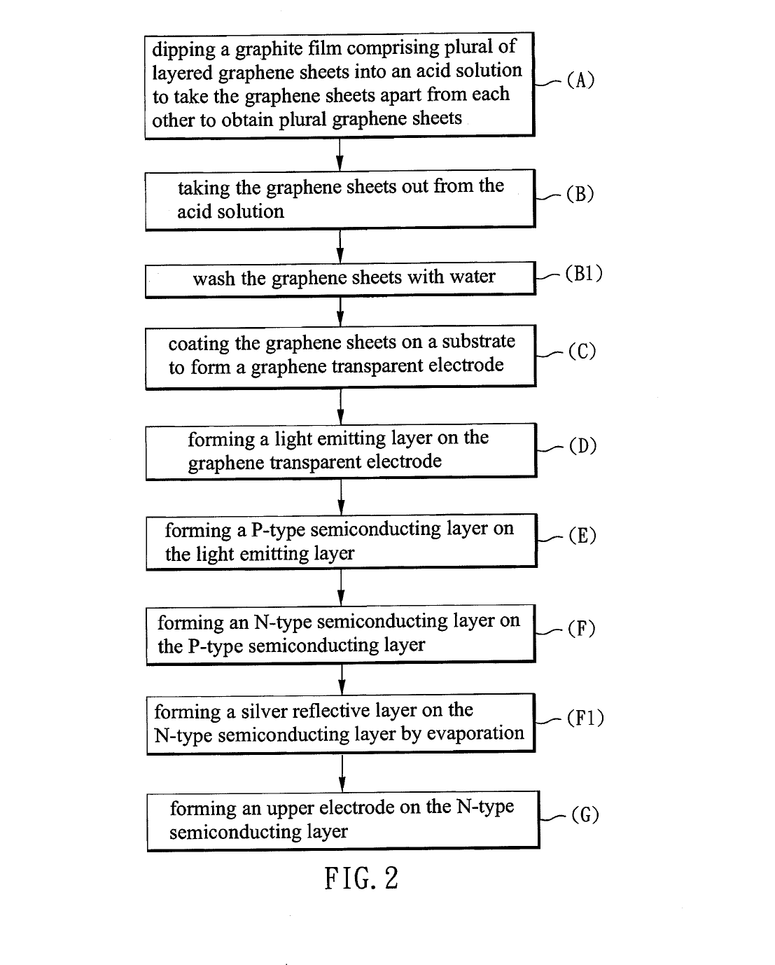

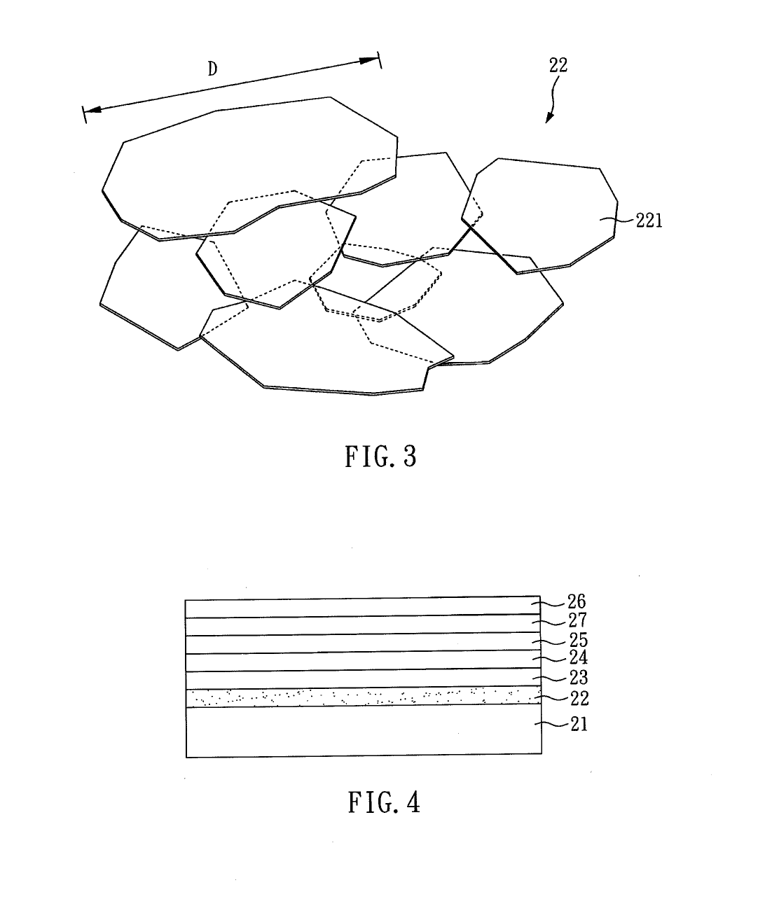

Reference with FIG. 2, a process flow chart of fabricating a gLED of the present example is shown. First, (A) the graphite film comprising plural of layered graphene sheets formed above is dipped into a sulfuric acid solution to separate the graphene sheets from each other to obtain plural graphene sheets. Then, (B) the graphene sheets are taken out from the sulfuric acid solution by using a copper mesh with pore size of 100 μm, and followed with (B1) washing the graphene sheets taken out from the acid solution with deionized water. After that, (C) the graphene sheets are coated on a substrate by spin coating with a magnetic field to form a graphene transparent electrode having a thickness of about 30 nm, in which the graphene sheets can be aligned by the magnetic field and therefore the transporting speed of the electrical current can be increased in a specific direction. The formed graphene transparent electrode is in a configuration as shown in FIG. 3.

Reference with FIG. 3, the graphene transparent electrode 22 of the present invention comprises plural graphene sheets 221 wherein the graphene sheets 221 electrically connect with each other by overlapping with each other. In the present example, each of the graphene sheets 221 has a diameter D of about 100 μm, the quantity of the graphene sheets in the graphene transparent electrode is about 80, the electrical resistance of the graphene transparent electrode is about 10⁻³ Ω/cm, and the light transmittance of the graphene transparent electrode is about 85%.

Then, (D) fluorescent powder is used to form a light emitting layer on the graphene transparent electrode by a printing method. After that, (E) a P-type semiconducting layer is formed on the light emitting layer. Herein, the P-type semiconducting layer is graphene doped with boron. Then, (F) an N-type semiconducting layer is formed on the P-type semiconducting layer, in which the N-type semiconducting layer is a graphene layer doped with nitrogen. Subsequently, (F1) a silver reflective layer is formed on the N-type semiconducting layer by evaporation. Finally, (G) a copper upper electrode is formed on the silver reflective layer, and a gLED (graphene-LED) of the present example is thus formed.

According to the present example, the graphene transparent electrode, the N-type semiconducting layer, and the P-type semiconducting layer are all made from graphene, thus the fabricating cost of the gLED can be efficiently reduced.

As shown in FIG. 4, the gLED provided by the present example is shown. The gLED of the present example comprises: a substrate 21, a graphene transparent electrode 22, a light emitting layer 23, a P-type semiconducting layer 24, an N-type semiconducting layer 25, and an upper electrode 26, and a reflective layer 27. The graphene transparent electrode 22 locating on the substrate 21 and comprising plural graphene sheets 221 (reference with FIG. 3), wherein the graphene sheets 221 electrically connect with each other by overlapping with each other. The light emitting layer 23 locates on the graphene transparent electrode 22. The P-type semiconducting layer 24 locates on the light emitting layer 23. The N-type semiconducting layer 25 locates on the P-type semiconducting layer 24. The upper electrode 26 locates on the N-type semiconducting layer 25. The reflective layer 27 locates between N-type semiconducting layer 25 and the upper electrode 26. In the present example, lights are emitted from the substrate 21.

The graphene light emitting diode of the present invention is able to emit UV lights or blue lights; therefore, it can be applied to sterilization of food or photo-curing processing, for example. Comparing with a conventional ITO electrode, the graphene light emitting diode of the present invention comprising the graphene transparent electrode has a higher transparency, better electrical resistance, and lower thickness. Besides, in the gLED of the present invention, if a graphene sheet doped with boron is used as the P-type semiconducting layer, and a graphene sheet doped with nitrogen or white graphite is used as the N-type semiconducting layer, the total thickness of the gLED of the present invention can be further reduced to meet the requirement of being minimized for electronics, and can be applied to more critical objects such as rollable display, e-pictures, or e-papers.

The gLED of the present invention enables the transporting speed and image resolution of mobile communications to be increased. The gLED of the present invention further has the same advantages as those possessed by LEDs and OLEDs. When the substrate of the gLED of the present invention is a flexible plastic substrate such as PET plate, the gLED of the present invention can be applied as a flexible large area display or a rollable display.

The gLED of the present invention uses graphene as a raw material, and therefore the manufacturing cost can be largely lowered. Besides, due to a high transparency of the graphene sheets, the brightness of the gLED can be increased. Also, a longer lifespan can be achieved according to the gLED of the present invention compared with a conventional OLED. The gLED of the present invention also has advantage of being as ultra thin, with high chromaticity and low power consumption, whereby the gLED of the present invention is of high commercial value.

### Example 2

The same method as described in the example 1 is used here to provide a gLED of the present example, except that an aromatic tertiary amine compound is used to form the P-type semiconducting layer.

The P-type semiconducting layer, the light emitting layer, and the N-type semiconducting layer in the gLED of the present invention can be made of materials that are used in a conventional OLED. The materials used in the example 1 are most proper, but are not limited thereto.

### Example 3

The same method as described in the example 1 is used here to provide a gLED of the present example, except that a plastic substrate is used as the substrate herein.

The plastic substrate herein may be a flexible substrate, thus the gLED made in the present example is a flexible gLED.

### Example 4

The same method as described in the example 1 is used here to provide a gLED of the present example except that the step (F1) is eliminated, i.e. the gLED in the present example does not have a silver reflective layer.

The reflective layer in the present invention can be selectively added, which means the gLED of the present invention can work normally even without the reflective layer.

### Example 5

The same method as described in the example 1 is used here to provide a gLED of the present example, except that hexagonal boron nitride (i.e. white graphite) is used to replace the graphene layer doped with nitrogen to form the N-type semiconducting layer herein.

[Testing Example]

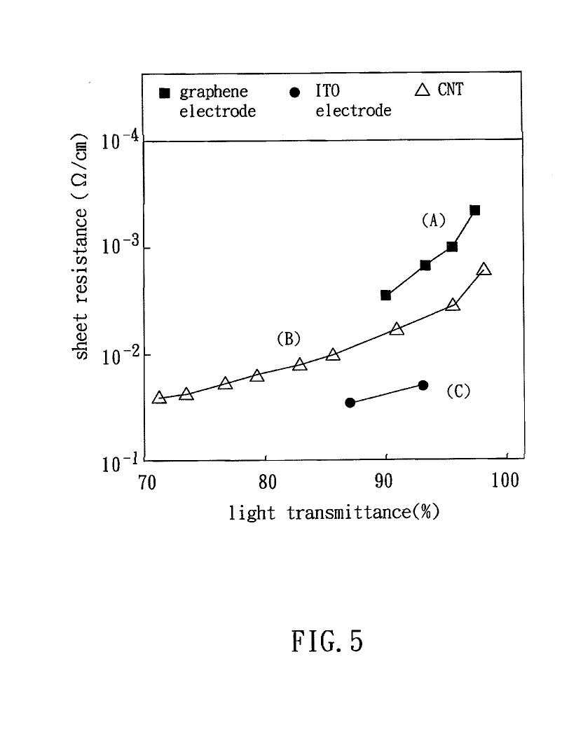

The graphene transparent electrode provided from the step (C) of the example 2 is taken to the light transmittance versus electrical resistance test, a conventional ITO electrode and a carbon nanotube electrode are taken as the control groups. The results are shown in FIG. 5.

As shown in FIG. 5, the sheet resistance of the graphene transparent electrode of the present invention is merely about 10⁻² to 10⁻⁴ Ω/cm, and the light transmittance or the sheet resistance of the graphene transparent electrode of the present invention (curve (A)) are both better than those of the conventional ITO electrode (curve (C)) and the carbon nanotube electrode (curve (B)).

Comparing with a conventional ITO electrode, the graphene light emitting diode of the present invention comprising the graphene transparent electrode has a higher transparency, better electrical resistance, and lower thickness. Besides, in the gLED of the present invention, if a graphene sheet doped with boron is used as the P-type semiconducting layer, and a graphene sheet doped with nitrogen or white graphite is used as the N-type semiconducting layer, the total thickness of the gLED of the present invention can be further reduced to meet the requirement of being minimized for electronics, and can be applied to more critical objects such as rollable display, e-pictures, or e-papers.

The gLED of the present invention uses graphene as a raw material, and therefore the manufacturing cost can be largely lowered. Besides, due to a high transparency of the graphene sheets, the brightness of the gLED can be increased. Also, a longer lifespan can be achieved according to the gLED of the present invention compared with a conventional OLED. The gLED of the present invention also has advantages such as being ultra thin, with high chromaticity and low power consumption, whereby the gLED of the present invention is of high commercial value.

Although the present invention has been explained in relation to its preferred embodiment, it is to be understood that many other possible modifications and variations can be made without departing from the scope of the invention as hereinafter claimed.

What is claimed is:

1. A graphene transparent electrode, which comprises:
at least one graphene sheet;
wherein the graphene sheets electrically connect with each other by overlapping with each other, each of the graphene sheets has a diameter from 10 μm to 1 mm, the quantity of the graphene sheets in the graphene transparent electrode is from 1 to 1000, the electrical resistance of the graphene transparent electrode is 1 Ω/cm or below, and the light transmittance of the graphene transparent electrode is 70% or above.

2. The graphene transparent electrode as claimed in claim 1, wherein the graphene sheet is doped with boron to form a P-type semiconducting layer.

3. The graphene transparent electrode as claimed in claim 1, wherein the graphene sheet is doped with nitrogen to form an N-type semiconducting layer.

4. The graphene transparent electrode as claimed in claim 1, wherein the thickness of the graphene transparent electrode is 10 nm to 1 mm.

5. The graphene transparent electrode as claimed in claim 1, wherein the thickness of the graphene sheet is 10 nm to 1 μm.

6. A graphene light emitting diode (gLED), which comprises:
a substrate;
a graphene transparent electrode locating on the substrate and comprising plural graphene sheets, wherein the graphene sheets electrically connect with each other by overlapping with each other;
a light emitting layer locating on the graphene transparent electrode;
a P-type semiconducting layer locating on the light emitting layer;
an N-type semiconducting layer locating on the P-type semiconducting layer; and
an upper electrode locating on the N-type semiconducting layer.

7. The graphene light emitting diode as claimed in claim 6, wherein the graphene sheets has a diameter from 10 μm to 1 mm, the quantity of the graphene sheets in the graphene transparent electrode is from 1 to 1000, the electrical resistance of the graphene transparent electrode is 1 Ω/cm or below, and the light transmittance of the graphene transparent electrode is 70% or above.

8. The graphene light emitting diode as claimed in claim 6, wherein the P-type semiconducting layer is a graphene layer doped with boron.

9. The graphene light emitting diode as claimed in claim 6, wherein the N-type semiconducting layer is a graphene layer doped with nitrogen.

10. The graphene light emitting diode as claimed in claim 6, wherein the N-type semiconducting layer is hexagonal boron nitride.

11. The graphene light emitting diode as claimed in claim 6, wherein the substrate is selected from a group consisted of a glass substrate, a quartz substrate, a silicon substrate, and a plastic substrate.

12. A method of fabricating a graphene light emitting diode (gLED), which comprises steps:
(A) dipping a graphite film comprising plural of layered graphene sheets into an acid solution to separate the graphene sheets from each other to obtain plural of graphene sheets;
(B) taking the graphene sheets out from the acid solution;
(C) coating the graphene sheets on a substrate to form a graphene transparent electrode;
(D) forming a light emitting layer on the graphene transparent electrode;
(E) forming a P-type semiconducting layer on the light emitting layer;
(F) forming an N-type semiconducting layer on the P-type semiconducting layer; and
(G) forming an upper electrode on the N-type semiconducting layer.

13. The method of fabricating a graphene light emitting diode as claimed in claim 12, wherein the graphite film is fabricated by steps: (A1) providing a substrate; (A2) coating a graphite powder on the substrate to form a graphite layer on the substrate; and (A3) heat-treat the graphite layer formed on the substrate under vacuum or oxygen-free atmosphere.

14. The method of fabricating a graphene light emitting diode as claimed in claim 13, wherein the temperature of the heat-treating of the step (A3) is 1000° C. to 1500° C.

15. The method of fabricating a graphene light emitting diode as claimed in claim 12, wherein in the step (C), the graphene sheets are coated on the substrate by a spin coating method.

16. The method of fabricating a graphene light emitting diode as claimed in claim 12, wherein in the step (C), the thickness of the graphene sheet is 10 nm to 1 μm.

17. The method of fabricating a graphene light emitting diode as claimed in claim 12, wherein in the step (C), when the graphene sheets is coated on the substrate, a magnetic field is applied to enable alignment of the graphene sheets.

18. The method of fabricating a graphene light emitting diode as claimed in claim 12, wherein in the step (B), a mesh with pore size of 1 μm to 100 μm is used to remove the graphene sheets from the acid solution.

19. The method of fabricating a graphene light emitting diode as claimed in claim 12, wherein in the step (A), the acid is selected from a group consisted of: sulfuric acid, hydrochloric acid, nitric acid, and a combination thereof.

20. The method of fabricating a graphene light emitting diode as claimed in claim 12, wherein in the step (E), the P-type semiconducting layer is made of graphene doped with boron, and the P-type semiconducting layer is made by coating the graphene sheets doped with boron on the graphene transparent electrode by a spin coating method.

21. The method of fabricating a graphene light emitting diode as claimed in claim 12, wherein in the step (F), the N-type semiconducting layer is a graphene layer doped with nitrogen.

22. The method of fabricating a graphene light emitting diode as claimed in claim 12, wherein in the step (F), the N-type semiconducting layer is hexagonal boron nitride.
